(19) United States
(12) Patent Application Publication
(10) Pub. No.: US 2025/0076374 A1
(43) Pub. Date: Mar. 6, 2025

(54) SEMICONDUCTOR DEVICE HANDLING APPARATUS AND SEMICONDUCTOR DEVICE TESTING APPARATUS

(71) Applicant: ADVANTEST Corporation, Tokyo (JP)

(72) Inventors: Aritomo Kikuchi, Tokyo (JP); Hideo Hara, Tokyo (JP)

(73) Assignee: ADVANTEST Corporation, Tokyo (JP)

(21) Appl. No.: 18/776,540

(22) Filed: Jul. 18, 2024

(30) Foreign Application Priority Data
Aug. 31, 2023 (JP) 2023-141546

(51) Int. Cl. G01R 31/311; G01R 31/28

(52) U.S. Cl. CPC G01R 31/311; G01R 31/2893

(57) ABSTRACT

A semiconductor device handling apparatus that moves a device under test (DUT) so that a terminal on a first surface of the DUT contacts a contact part of a semiconductor device testing apparatus, the semiconductor device handling apparatus includes a holding part that holds a second surface of the DUT and an optical probe that inputs and outputs an optical signal to and from an optical connection part on the second surface of the DUT.

### CROSS-REFERENCE TO RELATED APPLICATIONS

The present application claims priority to Japanese Patent Application No. 2023-141546, filed on Aug. 31, 2023. The contents of this application are incorporated herein by reference in their entirety.

### BACKGROUND

### Technical Field

The present invention relates to a semiconductor device handling apparatus that handles a semiconductor device to be tested (DUT: Device Under Test) including an electrical circuit and an optical circuit for testing the DUT and a semiconductor device testing apparatus that tests the DUT.

### Discussion of the Background

An electrical component testing apparatus that aligns an electrical component with respect to a probe card by an alignment unit and presses the electrical component against the probe card to test the electrical component is known (refer to, for example, Patent Document 1).

### PATENT DOCUMENT

PATENT DOCUMENT 1: JP 2016-85203 A

In the above-described electronic component testing apparatus, the electronic component testing apparatus is designed to test only electronic components and cannot test semiconductor devices each of which includes an optical circuit in addition to the electrical circuit.

### SUMMARY

One or more embodiments provide a semiconductor device handling apparatus and a semiconductor device testing apparatus for testing a semiconductor device including an electrical circuit and an optical circuit.

An aspect 1 of one or more embodiments is a semiconductor device handling apparatus that moves a device under test (DUT) to contact a terminal disposed on a first surface of the DUT with a contact part, comprising: a holding part that holds a second surface of the DUT; and an optical probe that inputs and outputs an optical signal to and from an optical connection part disposed on the second surface of the DUT.

An aspect 2 of one or more embodiments may be the semiconductor device handling apparatus of the aspect 1, wherein the semiconductor device handling apparatus may comprise: a first moving device that relatively moves the holding part with respect to the contact part to relatively align the terminal of the DUT with respect to the contact part; and a second moving device that relatively moves the optical probe with respect to the DUT held by the holding part to relatively align the optical probe with respect to the optical connection part of the DUT.

An aspect 3 of one or more embodiments may be the semiconductor device handling apparatus of the aspect 2, wherein the first moving device may be disposed on an opposite side of the DUT with respect to the holding part, and the second moving device may be disposed on an opposite side of the DUT with respect to the optical probe.

An aspect 4 of one or more embodiments may be the semiconductor device handling apparatus of the aspect 2 or 3, wherein the first moving device may relatively move the holding part and the second moving device with respect to the contact part.

An aspect 5 of one or more embodiments may be the semiconductor device handling apparatus of any one of the aspects 2 to 4, wherein the first moving device may comprise a support member to which the holding part is fixed, and the second moving device may be fixed to the support member and may relatively move the optical probe with respect to the holding part.

An aspect 6 of one or more embodiments may be the semiconductor device handling apparatus of any one of the aspects 2 to 5, wherein the holding part may comprise: a contact surface that contacts the second surface of the DUT; and a recess that opens to the contact surface and in which the optical probe is inserted, and the recess may have a size that allows the optical probe to relatively move with respect to the holding part.

An aspect 7 of one or more embodiments may be the semiconductor device handling apparatus of the aspect 5, wherein the holding part may comprise: a contact surface that contacts the second surface of the DUT; and an insertion hole that opens to the contact surface, and the optical probe may be inserted in the insertion hole so that the optical probe is relatively movable with respect to the holding part.

An aspect 8 of one or more embodiments may be the semiconductor device handling apparatus of any one of the aspects 2, 3, 6, wherein the first moving device may be fixed to a base of the semiconductor device handling apparatus, and the second moving device may be fixed to the base independently of the first moving device.

An aspect 9 of one or more embodiments may be the semiconductor device handling apparatus of any one of the aspects 1 to 8, wherein the optical probe may comprise an optical transmission path that transmits an optical signal.

An aspect 10 of one or more embodiments may be the semiconductor device handling apparatus of any one of the aspects 1 to 9, wherein the holding part may comprise: a contact surface that contacts the second surface of the DUT; and a temperature adjusting mechanism that adjusts a temperature of the DUT via the contact surface.

An aspect 11 of one or more embodiments may be the semiconductor device handling apparatus of any one of the aspects 1 to 10, wherein the holding part may comprise: a contact surface that contacts the second surface of the DUT; and a suction holding mechanism that opens to the contact surface and holds the DUT by suction.

An aspect 12 of one or more embodiments may be the semiconductor device handling apparatus of any one of the aspects 1 to 11, wherein the semiconductor device handling apparatus may comprise a first moving device that relatively moves the holding part with respect to the contact part to press the DUT holding by the holding part against the contact part and contact the terminal of the DUT with the contact part.

An aspect 13 of one or more embodiments may be the semiconductor device handling apparatus of any one of the aspects 1 to 12, wherein the DUT may comprise a die that comprises the optical connection part.

An aspect 14 of one or more embodiments may be the semiconductor device handling apparatus of the aspect 13, wherein the DUT may comprise a board that has the terminal and on which the die is mounted.

An aspect 15 of one or more embodiments may be the semiconductor device handling apparatus of any one of the aspects 1 to 14, wherein the optical connection part may include a grating coupler.

An aspect 16 of one or more embodiments may be the semiconductor device handling apparatus of any one of the aspects 1 to 15, wherein the contact part may include a probe card comprising a contactor that contacts the terminal of the DUT.

An aspect 17 of one or more embodiments is a semiconductor device testing apparatus that tests a device under test (DUT), comprising: a contact part that inputs and outputs an electrical signal to and from a terminal disposed on a first surface of the DUT; an optical probe that inputs and outputs an optical signal to and from an optical connection part disposed on a second surface of the DUT; and a testing device that is connected to the contact part to transmit the electrical signal and that is connected to the optical probe to transmit the optical signal.

An aspect 18 of one or more embodiments may be the semiconductor device testing apparatus of the aspect 17, wherein the semiconductor device testing apparatus may comprise the semiconductor device handling apparatus of any one of the aspects 1 to 16.

According to one or more embodiments, the optical probe inputs and outputs the optical signal to and from the optical connection part disposed on the second surface of the DUT. Therefore, it is possible to provide the semiconductor device handling apparatus and the semiconductor device testing apparatus for testing the semiconductor device including the electrical circuit and the optical circuit.

### BRIEF DESCRIPTION OF THE DRAWINGS

FIG. 1 is a diagram showing the overall configuration of the semiconductor device testing apparatus and the internal structure of the handler in one or more embodiments.

FIG. 2 is a cross-sectional view of the thermal chuck and optical probe unit and a block diagram showing the control system in one or more embodiments.

FIG. 3 is a plan view of the thermal chuck in one or more embodiments.

FIG. 4A is a cross-sectional and plan view showing a modified example of the thermal chuck and the optical probe unit in one or more embodiments.

FIG. 4B is a cross-sectional and plan view showing a modified example of the thermal chuck and the optical probe unit in one or more embodiments.

FIG. 5A is a cross-sectional view showing the method of pressing the DUT against the probe card by the handler in one or more embodiments.

FIG. 5B is a cross-sectional view showing the method of pressing the DUT against the probe card by the handler in one or more embodiments.

FIG. 5C is a cross-sectional view showing the method of pressing the DUT against the probe card by the handler in one or more embodiments.

FIG. 6 is a diagram showing a part of the internal structure of the handler in one or more embodiments.

### DESCRIPTION OF THE EMBODIMENTS

Hereinafter, embodiments will be described with reference to the drawings.

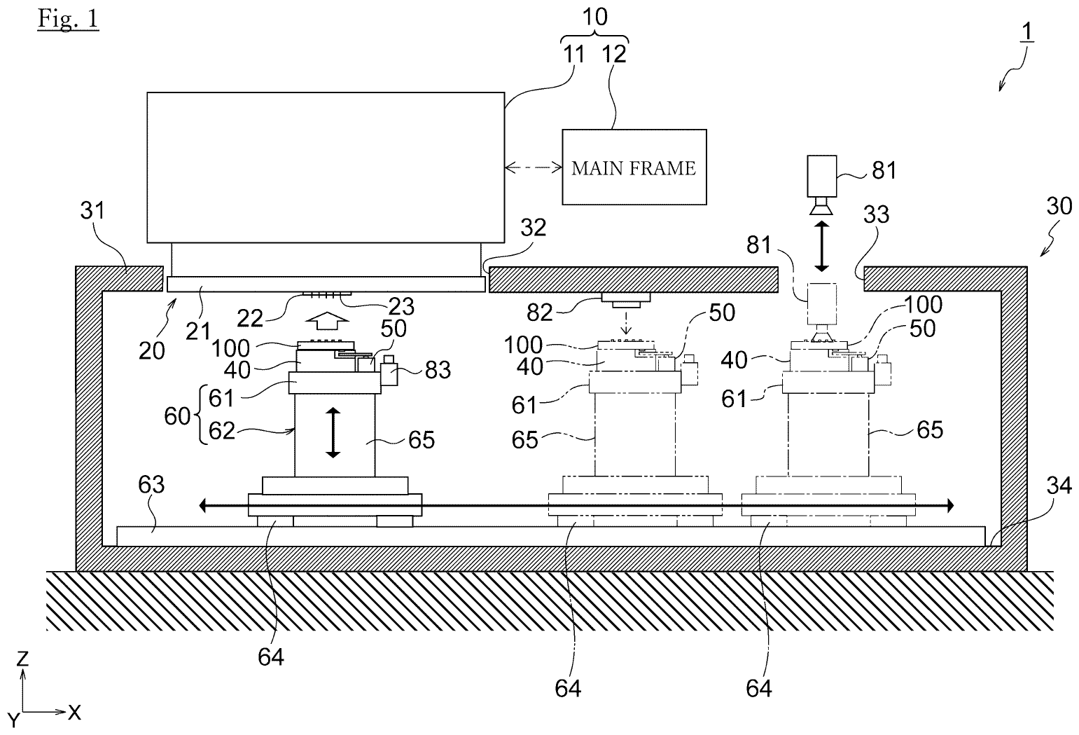

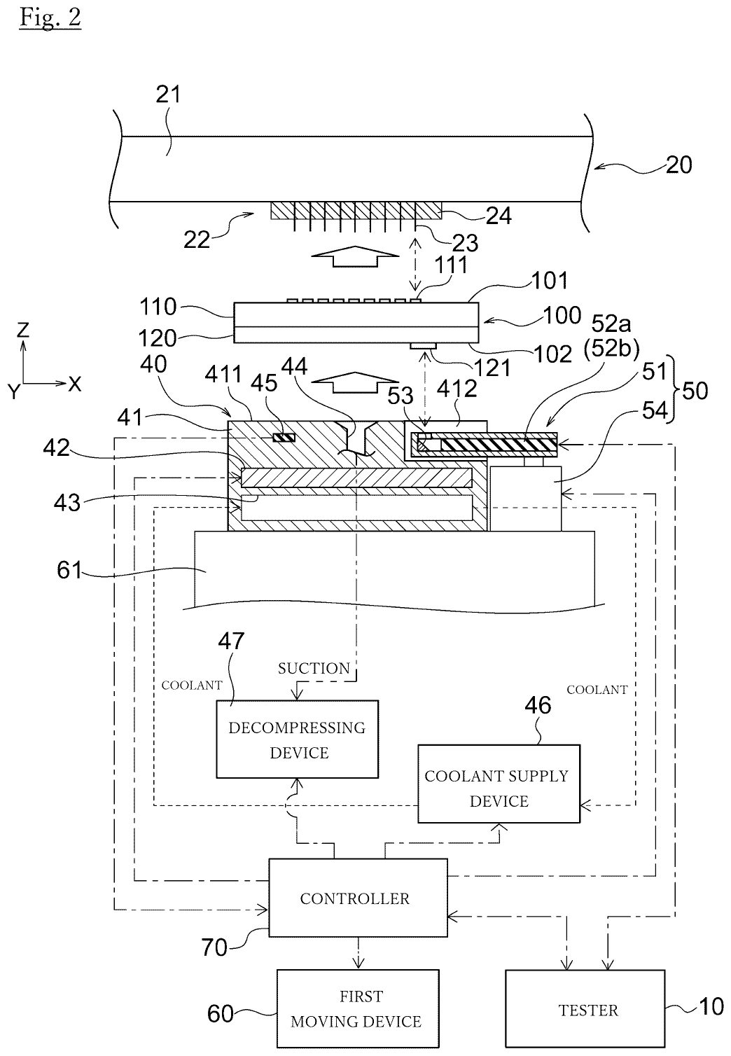

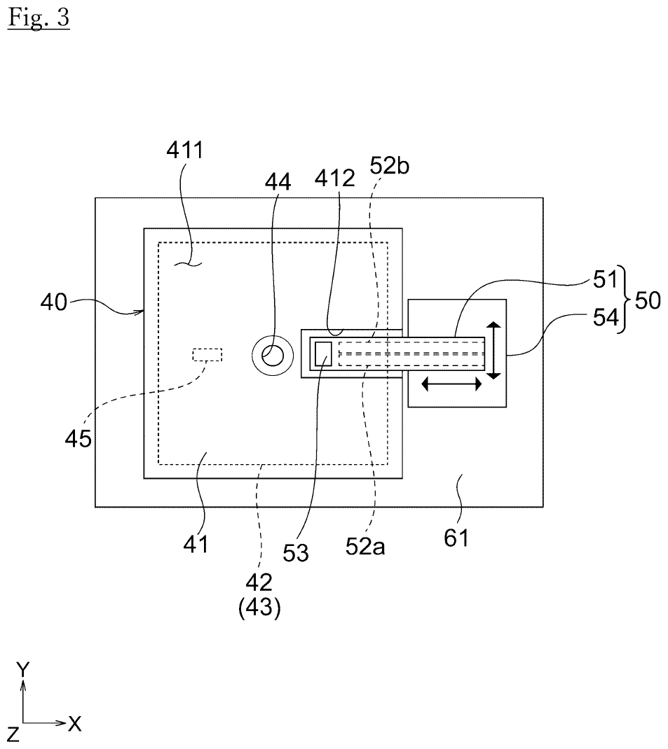

FIG. 1 is a diagram showing the overall configuration of the semiconductor device testing apparatus 1 and the internal structure of the handler 30 in one or more embodiments. FIG. 2 is a cross-sectional view of the thermal chuck 40 and optical probe 50 unit and a block diagram showing the control system in one or more embodiments. FIG. 3 is a plan view of the thermal chuck 40 in one or more embodiments. Although the DUT 100 is separated from the thermal chuck 40 in FIG. 2 for ease of understanding, in reality the DUT 100 is held by the thermal chuck 40 and therefore the DUT 100 is in contact with the thermal chuck 40.

The semiconductor device testing apparatus 1 in one or more embodiments is an apparatus for testing a semiconductor device 100. As shown in FIG. 1, the semiconductor device testing apparatus 1 includes a tester 10, a probe card 20, and a handler 30. The handler 30 corresponds to an example of the “semiconductor device handling apparatus” in the aspect of one or more embodiments.

The DUT 100 that is the test target of the semiconductor device testing apparatus 1 is a semiconductor device capable of handling electrical and optical signals. That is, the DUT 100 is a hybrid circuit device including an electronic circuit and an optical circuit.

Specifically, as shown in FIG. 2, the DUT 100 includes a board 110 and a die 120. Although not particularly limited, a wiring board such as an interposer can be exemplified as a specific example of the board 110. The board 110 has terminals 111 for inputting and outputting electrical signals. The die 120 is a bare die (bare chip) formed by dicing a semiconductor wafer and is mounted on the board 110. The die 120 includes an optical connection part 121 for inputting and outputting an optical signal. The optical circuit including the optical connection part 121 is formed on the die 120 using, for example, silicon photonics technology. Although not particularly limited, for example, a grating coupler can be exemplified as a specific example of the optical connection part 121. While the terminals 111 are disposed on the upper surface 101 of the DUT 100, the optical connection part 121 is disposed on the lower surface 102 of the DUT 100.

The DUT 100 that is the test target of the semiconductor device testing apparatus 1 in one or more embodiments may be a bare die including terminals 111 and an optical connection part 121. That is, the DUT 100 to be tested may be an individual die before being mounted on a board.

During the test of the DUT 100, an electrical signal is input and output to and from the DUT 100 via the terminal 111, and an optical signal is input and output to and from the DUT 100 via the optical connection part 121. When the test is completed, for example, an optical fiber connected to an optical connector is connected to the optical connecting part 121 to form a final product. This final product is, for example, a CPO (Co-Packaged Optics) device.

The tester 10 is a test apparatus that tests a semiconductor device 100 using electrical and optical signals. As shown in FIG. 1, the tester 10 includes a test head 11 and a main frame (tester body) 12. The test head 11 is connected to the main frame 12 via a cable. The probe card 20 is electrically connected to the test head 11. The probe card 20 enters the inside of the handler 30 through an opening 32 formed in an upper base 31 of the handler 30.

The probe card 20 includes a wiring board 21 and a probe head 22 mounted on wiring board 21. As shown in FIG. 2, the probe head 22 includes a plurality of probes 23 and a housing 24. The probe card 20 corresponds to an example of the “contact part” in the aspect of one or more embodiments, and the probe 23 corresponds to an example of the “contactor” in the aspect of one or more embodiments.

The probe 23 is an electrical probe that contacts the terminal 111 of the DUT 100. The plurality of probes 23 are arranged to correspond to the plurality of terminals 111 of the DUT 100. Although not particularly limited, for example, a pogo pin, a vertical probe needle, a cantilever-type probe needle, an anisotropic conductive rubber sheet, a bump provided on a membrane, or a contactor manufactured using MEMS technology can be exemplified as a specific example of the probe 23.

The probes 23 are held by the housing 24, and the probe head 22 is mounted to the wiring board 21 by fixing the housing 24 to the wiring board 21 by screws or the like. The wiring board 21 may directly hold the probes 23, and the housing 24 can be omitted in this case.

As shown FIG. 1 and FIG. 2, the handler 30 includes a thermal chuck 40, an optical probe unit 50, a first moving device 60, and a controller 70. The thermal chuck 40 corresponds to an example of the “holding part” in the aspect of one or more embodiments.

The thermal chuck 40 includes a suction holding mechanism that sucks and holds the DUT 100, and a temperature adjusting mechanism that adjusts the temperature of the DUT 100. Specifically, as shown in FIG. 2, the thermal chuck 40 includes a holding member 41, a heater 42, a cooling flow path 43, a suction flow path 44, and a temperature sensor 45.

The holding member 41 is a block-shaped member having a flat contact surface 411 that contacts the lower surface 102 of the DUT 100. The heater 42 is embedded in the holding member 41. The heater 42 is provided inside the holding member 41 so that the heater 42 corresponds to the entire area of the contact surface 411. Although not particularly limited, a ceramic heater such as an aluminum nitride heater, a silicon nitride heater, and a PTC heater, a polyimide heater, and a cartridge heater can be exemplified as a specific example of the heater 42. The heater 42 is connected to the controller 70. The heater 42 generates heat by power supplied from the controller 70 and heats the DUT 100 via the contact surface 411.

Two types of flow paths 43 and 44 are formed inside the holding member 41. Similar to the heater 42 described above, the cooling flow path 43 is provided inside the holding member 41 so that the cooling flow path 43 corresponds to the entire area of the contact surface 411. A coolant supply device 46 is connected to the cooling flow path 43, and a coolant having a temperature lower than room temperature is supplied from the coolant supply device 46 to the cooling flow path 43. As the coolant passes through the cooling flow path 43, the DUT 100 is cooled via the contact surface 411. A liquid or a gas may be used as the coolant flowing through the cooling flow path 43. Although not particularly limited, for example, water and fluorine-based inert liquid can be exemplified as a specific example of a liquid coolant. On the other hand, for example, air and nitrogen can be exemplified as a specific example of gas coolant.

The configuration of the temperature adjusting device that adjusts the temperature of the DUT 100 is not limited to the above. Although not particularly shown, for example, a planar heater may be exposed from the upper surface of the holding member 41 and may directly contact the DUT 100. In this case, the upper surface of the heater constitutes the contact surface of the thermal head. Alternatively, instead of a heater, a hot medium having a temperature higher than room temperature may be passed through a flow path in the holding member 41. Alternatively, a Peltier element may be used as the heater, or a Peltier element may be used instead of the coolant. The holding member 41 may not include either a heating device or a cooling device.

On the other hand, the suction flow path 44 is formed in the holding member 41 so that one end of the suction flow path 44 opens to the contact surface 411. The other end of the suction flow path 44 is connected to a decompressing device 47. The suction flow path 44 is sucked by the decompressing device 47 in a state where the DUT 100 is placed on the contact surface 411 of the holding member 41. Thus, the DUT 100 is sucked and held by the holding member. For example, a vacuum pump can be exemplified as a specific example of the decompressing device 47.

The temperature sensor 45 is also embedded in the holding member 41. The temperature sensor 45 is provided inside the holding member 41 so that the temperature sensor 65 is located near the contact surface 411. The temperature sensor 45 detects the temperature of the DUT 100 via the contact surface 411. The temperature sensor 45 is connected to the controller 70 so that the temperature sensor 65 can output the detection result to the controller 70.

As shown in FIG. 2 and FIG. 3, the optical probe unit 50 includes an optical probe 51 and a second moving device 54. The optical probe 51 is an optical input/output part for inputting and outputting optical signals to and from the optical connection part 121 formed on the lower surface 102 of the DUT 100. The optical probe 51 includes optical fibers 52a and 52b and a mirror 53.

Each of the optical fibers 52a and 52b is arranged so that the optical axis thereof is along the XY plane in the figure, and the pair of optical fibers 52a and 52b are arranged in substantially parallel. The optical fibers 52a and 52b are connected to the tester 10 to transmit optical signals. The mirror 53 is arranged on the optical axes of the optical fibers 52a and 52b.

When testing the DUT 100, in a state where the end of the optical probe 51 faces the optical connection part 121 of the DUT 100, an optical signal input from the tester 10 is output from one optical fiber 52a toward the mirror 53, and the optical signal is reflected by the mirror 53 and is input to the optical connection part 121 of the DUT 100. On the other hand, an optical signal output from the optical connection part 121 of the DUT 100 is reflected by the mirror 53 and is input to the tester 10 via the other optical fiber 52b. That is, in one or more embodiments, one optical fiber 52a functions as an optical transmission path for input, and the other optical fiber 52b functions as an optical transmission path for output.

In one or more embodiments, although the optical probe 51 inputs and outputs optical signals in a non-contact state with the optical connection part 121 of the DUT 100, the optical probe 51 and the optical connection part 121 may be in contact with each other. The optical probe 51 may include optical elements other than the optical fibers 52a and 52b and the mirror 53 as an optical transmission path for transmitting optical signals.

The optical probe 51 is supported by a second moving device 54. The second moving device 54 is an alignment device that aligns (positions) the optical probe 51 with respect to the optical connection part 121 of the DUT 100. The second moving device 54 is capable of moving the optical probe 51 in the X and Y axis directions in the figure and rotating (θz) the optical probe 51 around the Z axis. The degree of freedom of the second moving device 54 may be six degrees of freedom including the movement in the Z axis direction and the rotations (θx and θy) around the X and Y axes in addition to the above three degrees of freedom.

Although not particularly limited, the second moving device 54 includes, for example, an actuator, a transmission mechanism, and a guide mechanism. Although not particularly limited, for example, a motor including an electric motor (rotary motor, linear motor, etc.), and an electric actuator including the electric motor and a piezoelectric actuator (actuator using a piezoelectric element) can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The first moving device 60 is a device that moves the thermal chuck 40 and the optical probe unit 50. As shown in FIG. 1, the first moving device 60 includes a support member 61 and a moving mechanism 62 that moves the support member 61. The first moving device 60 aligns (positions) the DUT 100 with respect to the probe card 20 so that the plurality of terminals 111 of the DUT 100 respectively face the plurality of probes 23 of the probe head 22.

The thermal chuck 40 and the optical probe unit 50 are supported by a flat support member 61. Specifically, as shown in FIG. 2 and FIG. 3, the holding member 41 of the thermal chuck 40 and the second moving device 54 of the optical probe unit 50 are fixed to the support member 61. Therefore, the second moving device 54 is capable of relatively moving the optical probe 51 with respect to the thermal chuck 40. That is, the second moving device 54 is capable of relatively moving the optical probe 51 with respect to the optical connection part 121 of the DUT 100 that is sucked and held by the thermal chuck 40. Accordingly, in one or more embodiments, the alignment (positioning) of the optical probe 51 with respect to the optical connection part 121 can be performed independently of the alignment (positioning) of the terminal 111 of the DUT 100 with respect to the electric probe 23 of the probe card 20.

A groove 412 is formed in the holding member 41 of the thermal chuck 40. The groove 412 is formed in the holding member 41 so that the groove 412 opens to the contact surface 411 that contacts the DUT 100. The optical probe 51 is inserted in the groove 412. A space is secured between the optical probe 51 and the groove 412 so that the optical probe 51 can be moved and rotated by the second moving device 54 described above.

It is possible to increase the contact area of the thermal chuck 40 with the DUT 100 while the optical probe 51 faces the optical connection part 121 of the DUT 100 by mutually overlapping the holding member 41 and the optical probe 51. As a result, the temperature of the DUT 100 can be efficiently adjusted by the thermal chuck 40, and the DUT 100 can be stably pressed against the probe card 20. The groove 412 corresponds to an example of the “recess” in the aspect of one or more embodiments.

The moving mechanism 62 is capable of moving the support member 61 in the X, Y, and Z axis directions in the figure and rotating the support member 61 around the Z axis (θz). The moving mechanism 62 includes an X drive unit including an X-direction rail 63, a Y drive unit including a Y-direction rail 64, and a Z drive unit 65.

As shown in FIG. 1, the X direction rail 63 is disposed on the lower base 34 of the handler 30 and extends in the X direction. The Y direction rail 64 is slidably held by the X direction rail 63 and can move in the X direction. The Z drive unit 65 is slidably held by the Y direction rail 64 and is movable in the Y direction. The above-described support member 61 is attached to the Z driving unit 65. The Z drive unit 65 is capable of raising and lowering the support member 61 and rotating the support member 61 about the Z axis. As a result, the thermal chuck 40 and the optical probe unit 50 supported by the support member 61 can be moved in XYZ direction and can rotate about the Z axis by the moving mechanism 62.

Although not particularly limited, each of the X drive unit, the Y drive unit and a Z drive unit 65 of the moving mechanism 62 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

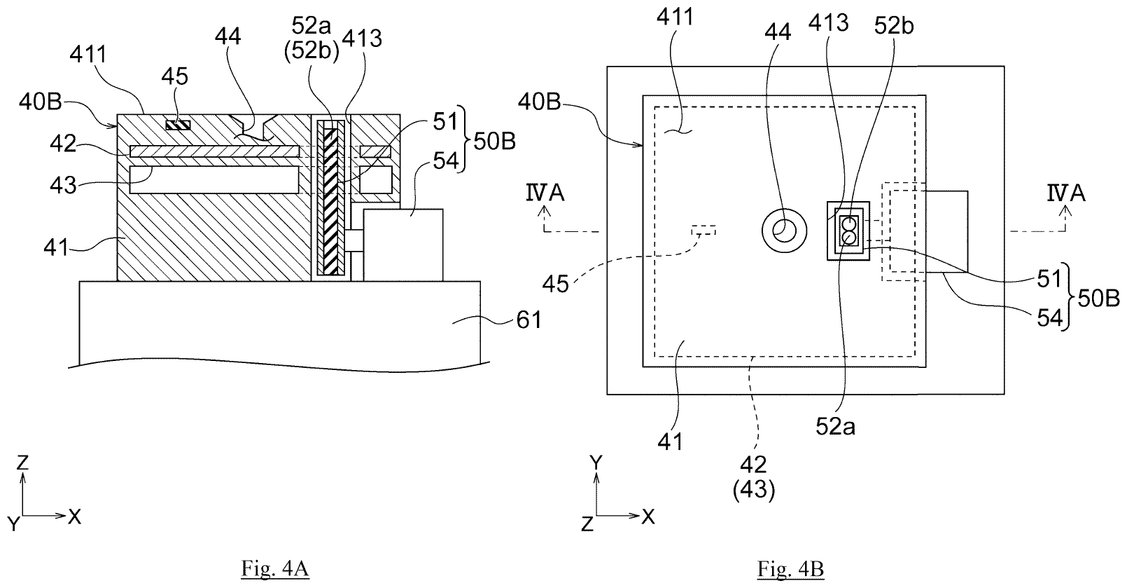

The configuration of the thermal chuck and the optical probe unit is not limited to the above. For example, the thermal chuck and the optical probe unit may be configured as shown in FIG. 4A and FIG. 4B. FIG. 4A and FIG. 4B are cross-sectional and plan views showing a modified example of the thermal chuck and the optical probe unit in one or more embodiments. FIG. 4A is a cross-sectional view along the line IVA-IVA in FIG. 4B.

In the thermal chuck 40B and the optical probe unit 50B shown in FIG. 4A and FIG. 4B, an insertion hole 413 is formed in the holding member 41 along the Z axis direction so that the insertion hole 413 opens to the contact surface 411. The optical probe 51 is inserted in the insertion hole 413. In the modified example, the optical probe 51 does not include a mirror 53 because the optical axes of the optical fibers 52a and 52b are arranged in the Z axis direction in the figure. A space is secured between the optical probe 51 and the insertion hole 413 so that the optical probe 51 can be moved and rotated by the second moving device 54. Thus, it is possible to increase the contact area of the thermal chuck 40 with the DUT 100 while the optical probe 51 faces the optical connection part 121 of the DUT 100 by disposing the optical probe 51 in the insertion hole 413 formed in the holding member 41.

The controller 70 includes, for example, a computer. Although not specifically shown, the computer is an electronic computer that includes a CPU (processor), a main memory (such as a RAM), an auxiliary memory device (such as a hard disk or SSD), an interface, and the like. The control described below is functionally realized, for example, by the controller 70 executing a program. The controller 70 may be configured with a circuit board instead of a computer.

As shown in FIG. 2, the controller 70 is electrically connected to the heater 42, the temperature sensor 45, and the coolant supply device 46. The controller 70 controls the heater 42 and the coolant supply device 46 based on the detection result of the temperature sensor 45 to adjust the temperature of the DUT 100 through the holding member 41. The controller 70 may control the heater 42 and the coolant supply device 46 based on the output of the temperature detecting circuit included in the DUT 100 instead of the temperature sensor 45. Although not particularly limited, for example, a circuit including a thermal diode and included in the DUT 100 can be exemplified as a specific example of the temperature detecting circuit.

The controller 70 is electrically connected to the decompressing device 47. The controller 70 controls the decompressing device 47 so that the thermal chuck 40 holds the DUT 100 by suction and releases the DUT 100. The controller 70 is connected to the tester 10 so that the controller 70 is capable of transmitting electrical signals to and from the tester 10. The tester 10 has the function to test the electronic circuit of the DUT 100 and the function to test the optical circuit of the DUT 100. The tester 10 is connected to the optical fibers 52a and 52b of the optical probe 51 so that the tester 10 is capable of transmitting optical signals to and from the optical fibers 52a and 52b of the optical probe 51. The function to test the optical circuit of the DUT 100 includes the function of the light source and the function to measure the intensity of light. The controller 70 is connected to the first and second moving devices 60 and 54 so that the controller 70 is capable of outputting control signals to the first and second moving devices 60 and 54. The controller 70 can control the operation of the moving devices 60 and 54. The tester 10 may not have the function to test the optical circuit of the DUT 100. In this case, an external measuring device having the function to test the optical circuit of the DUT 100 is connected to the optical fibers 52a and 52b of the optical probe 51 so that the external measuring device is capable of transmitting optical signals to and from the optical fibers 52a and 52b of the optical probe 51. The external measuring device is a testing device independent of the tester 10 and is, for example, electrically connected to the tester 10.

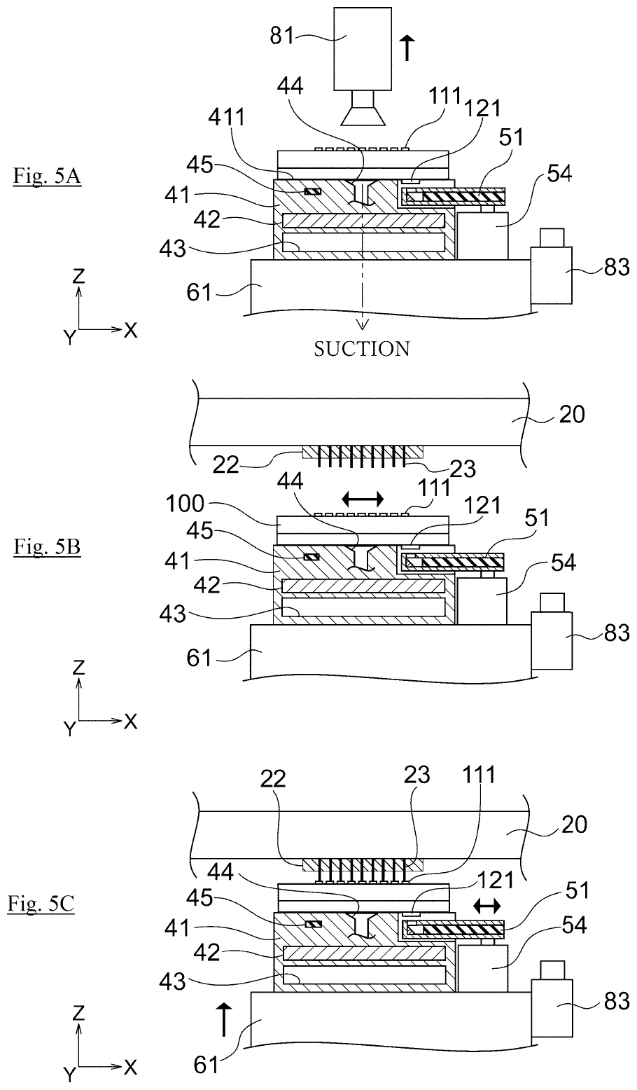

Below, the method of pressing the DUT 100 against the probe card 20 by the handler 30 described above will be explained with reference to FIG. 1 and FIG. 5A to FIG. 5C. FIG. 5A to FIG. 5C are cross-sectional views showing the method of pressing the DUT 100 against the probe card 20 by the handler 30 in one or more embodiments.

First, as shown by the chain line in FIG. 1, the first moving device 60 moves the thermal chuck 40 and the optical probe unit 50 so that the thermal chuck 40 is located below the opening 33 of the upper base 31 of the handler 30. In this state, the transporting device 81 included in the handler 30 picks up the DUT 100 before testing from a tray or plate and transports the DUT 100 to the thermal chuck 40 through the opening 33.

Although not particularly limited, a pick-and-place device including a suction pad can be exemplified as a specific example of the transporting device 81. Although not particularly limited, for example, a custom tray compliant with JEDEC (Joint Electron Device Engineering Council) standards can be exemplified as a specific example of the above-described tray. For example, a buffer plate capable of holding the DUT 100 can be exemplified as the above-described plate. When the DUT 100 is a die itself, the DUT 100 before testing may be held on a ring frame (wafer ring) instead of the above-described tray or plate.

As shown in FIG. 5A, when the DUT 100 is placed on the contact surface 411 by the transporting device 81, the controller 70 drives the decompressing device 47, and the thermal chuck 40 sucks and holds the DUT 100. Further, when the DUT 100 is placed on the contact surface 411, the controller 70 starts controlling the heater 42 and the coolant supply device 46 to adjust the temperature of the DUT 100.

Next, as shown by the two-dot chain line in FIG. 1, the first moving device 60 moves the thermal chuck 40 and the optical probe unit 50 so that the DUT 100 faces the camera 82 held by the upper base 31 of the handler 30. Then, the camera 82 captures the image of the DUT 100 held by the thermal chuck 40. The probe head 22 of the probe card 20 has been previously imaged by the camera 83 attached to the support member 61 of the first moving device 60. The image processing function of the controller 70 recognizes the relative positional relationship between the terminal 111 of the DUT 100 and the probe 23 of the probe card 20 based on the images captured by cameras 82 and 83. The timing for capturing the image of the probe card 20 by the camera 83 is, for example, when the probe card is replaced in response to a change in the type of the DUT 100.

Next, as shown by the solid line in FIG. 1, the first moving device 60 moves the thermal chuck 40 and the optical probe unit 50 so that the DUT 100 faces the probe head 22 of the probe card 20. During this movement, the camera 83 may capture the image of the probe head 22 of the probe card 20.

Next, as shown in FIG. 5B, the position of the thermal chuck 40 is finely adjusted by the first moving device 60 based on the relative positional relationship between the terminal 111 of the DUT 100 and the probe 23 of the probe card 20 recognized using the cameras 82 and 83. As a result, the plurality of terminals 111 of the DUT 100 relatively face the plurality of probes 23 of the probe head 22, and the DUT 100 is relatively aligned (positioned) with respective to the probe card 20.

Next, as shown in FIG. 5C, the first moving device 60 raises the thermal chuck 40 and the optical probe unit 50 and presses the DUT 100 against the probe card 20 to electrically connect them. In this state, the plurality of terminals 111 of the DUT 100 are in contact with the plurality of probes 23 of the probe card 20.

Next, the second moving device 54 relatively aligns (positions) the end of the optical probe 51 with respect to the optical connection part 121 of the DUT 100 by finely adjusting the position of the optical probe 51. Although not particularly limited, the positional relationship between the optical probe 51 and the optical connection part 121 is recognized based on, for example, the intensity of light output from the optical connection part 121.

Specifically, light output from the light source included in the tester 10 is irradiated from the one optical fiber 52a of the optical probe 51 toward the lower surface 102 of the DUT 100 including the optical connection part 121. Then, the other optical fiber 52b receives the light output from the optical connection part 121 via a loopback circuit incorporated in the optical circuit of the DUT 100. While this operation is being performed, the second moving device 54 causes the optical probe 51 to scan along the lower surface 102 of the DUT 100. Then, the tester 10 measures the intensity of light output from the optical connection part 121, and the controller 70 stops the movement of the optical probe 51 at a position where the intensity of light is equal to or greater than a predetermined value. As a result, the optical probe 51 is relatively aligned (positioned) with respect to the optical connection part 121.

As with the relative positional relationship between the terminal 111 of the DUT 100 and the probe 23 of the probe card 20 described above, the relative positional relationship between the optical probe 51 and the optical connection part 121 may be recognized by cameras and an image processing. In this case, for example, the DUT 100 held by the transporting device 81 is imaged from below with a camera, and the optical probe 51 is imaged from above with another camera before the DUT 100 is placed on the thermal chuck 40, and the image processing function of the controller 70 recognizes the relative positional relationship between the optical probe 51 and the optical connection part 121 based on these images. Alternatively, the optical probe 51 may be coarsely aligned with respect to the optical connecting part 121 using image processing, and then the optical probe 51 may be precisely aligned based on the intensity of light.

When the DUT 100 is placed on the contact surface 411 by the transporting device 81 and the thermal chuck 40 sucks and holds the DUT 100 (as indicated by the chain line in FIG. 1), the alignment of the optical probe 51 with respect to the optical connection part 121 may be performed. That is, the alignment of the optical probe 51 with respect to the optical connection part 121 may be performed before electrically connecting the DUT 100 and the probe card 20.

Next, the tester 10 inputs an electrical signal to the DUT 100 via the electrical probe 23 and the terminal 111, and the tester 10 also inputs an optical signal to the DUT 100 via the optical probe 51 and the optical connection part 121. Then, the tester 10 determines the quality and characteristics of the DUT 100 based on the electrical signal output from the DUT 100 via the terminal 111 and the electrical probe 23 and the optical signal output from the DUT 100 via the optical connection part 121 and optical probe 51.

In one or more embodiments, because an optical signal can be input and output to and from the optical connection part 121 disposed on the lower surface 102 of the DUT 100 by the optical probe 51, it is possible to test the semiconductor device 100 including the electronic and optical circuits. In particular, in one or more embodiments, it is possible to test the DUT 100 that has a terminal 111 disposed on one surface 101 of the DUT 100 and an optical connection part 121 disposed on the other surface 102 of the DUT 100.

Further, in one or more embodiments, because the handler 30 includes the second moving device 54 that moves the optical probe 51 independently of the first moving device 60, it is possible to relatively align (position) the optical probe 51 with respect to the optical connection part 121 of the DUT 100 while the DUT 100 is sucked and held by the thermal chuck 40. Further, even if the accuracy of the alignment of the optical probe 51 with respect to the optical connection part 121 is higher than that of the electrical probe 23 with respect to the terminal 111, it is possible to align the optical probe 51 with respect to the optical connection part 121 with high accuracy by the second moving device 54.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

For example, although the semiconductor device testing apparatus 1 tests only one DUT 100 at a time in the above embodiments, the number of the DUTs 100 tested simultaneously by the semiconductor device testing apparatus 1 is not particularly limited to the above, and the semiconductor device testing apparatus 1 may simultaneously test a plurality of the DUTs 100 at the same time.

Although the optical probe unit 50 is supported by the support member 61 of the first moving device 60 and the first moving device 60 moves the optical probe unit 50 along with the thermal chuck 40 in the above embodiments, it is not necessary for the first moving device 60 to move the optical probe unit 50.

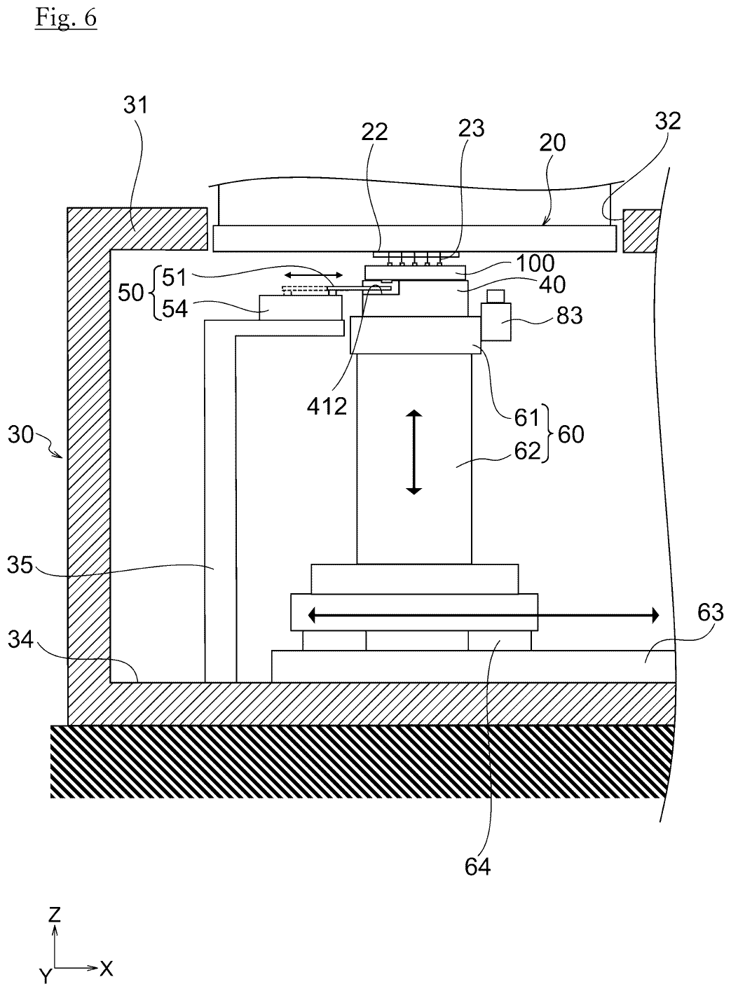

FIG. 6 is a diagram showing a part of the internal structure of the handler in one or more embodiments. As shown in FIG. 6, a support member 35 that is independent of the first moving device 60 may be fixed to the lower base 34 of the handler 30, and the optical probe unit 50 may be supported by the support member 35 and may be fixed to the support member 35 instead of the support member 61 of the first moving device 60. Therefore, because the length and movement of the optical fibers 52a and 52b can be reduced, it is possible to facilitate the routing of the optical fibers 52a and 52b in the handler 30, and it is possible to reduce the impact on the optical properties and lifespan of the optical fibers 52a and 52b. Further, even when the handler 40 includes a plurality of first moving devices 60, a single optical probe unit 50 can cope with it.

In this case, as shown in FIG. 6, in a state when the terminals 111 of the DUT 100 is in contact with the probes 23 of probe head 22 after the terminals 111 are aligned with respect to the probes 23, the optical probe 51 is inserted into the groove 412 of the holding member 41 of the thermal chuck 40. For example, the range of motion in the X axis direction of the second moving device 54 of the optical probe unit 50 is expanded, therefore the optical probe 51 can be moved in and out of the groove 412 of the thermal chuck 40 by the X direction movement of the second moving device 54.

The installing position of the support member 35 is not limited to the above-mentioned lower base 34, as long as it is a location where the support member 35 is relatively fixed to the frame of the handler 30 and cannot be moved. For example, the support member 35 may be fixed to the upper base 31 or the sidewall of the handler 30.

### EXPLANATIONS OF LETTERS OR NUMERALS

1 . . . Semiconductor device testing apparatus
10 . . . Tester (testing device)
11 . . . Test head
12 . . . Main frame
20 . . . Probe card (contact part)
21 . . . Wiring board
22 . . . Probe head
23 . . . Probe (contactor)
24 . . . Housing
30 . . . Handler (semiconductor device handling apparatus)
31 . . . Upper base
32 and 33 . . . Opening
34 . . . Lower base
35 . . . Support member
40 and 40B . . . Thermal chuck (holding part)
41 . . . Holding member
411 . . . Contact surface
412 . . . Groove (recess)
413 . . . Insertion hole
42 . . . Heater (temperature adjusting mechanism)
43 . . . Cooling flow path
44 . . . Suction flow path (suction holding mechanism)
45 . . . Temperature sensor
46 . . . Coolant supply device (temperature adjusting mechanism)
47 . . . Decompressing device
50 and 50B . . . Optical probe unit
51 . . . Optical probe
52a and 52b. . . Optical fiber (optical transmission path)
53 . . . Mirror
54 . . . Second moving device
60 . . . First moving device
61 . . . Support member
62 . . . Moving mechanism
63 . . . X direction rail
64 . . . Y direction rail
65 . . . Z driving mechanism
70 . . . Controller
81 . . . Transporting device
82 . . . Camera
83 . . . Camera
100 . . . DUT
101 . . . Upper surface (first surface)
102 . . . Lower surface (second surface)
110 . . . Board
111 . . . Terminal
120 . . . Die
121 . . . Optical connection part

What is claimed is:

1. A semiconductor device handling apparatus that moves a device under test (DUT) so that a terminal on a first surface of the DUT contacts a contact part of a semiconductor device testing apparatus, the semiconductor device handling apparatus comprising:
a holding part that holds a second surface of the DUT; and
an optical probe that inputs and outputs an optical signal to and from an optical connection part on the second surface of the DUT.

2. The semiconductor device handling apparatus according to claim 1, further comprising:
a first moving device that moves the holding part relative to the contact part and aligns the terminal of the DUT with respect to the contact part; and
a second moving device that moves the optical probe relative to the DUT held by the holding part and aligns the optical probe with respect to the optical connection part of the DUT.

3. The semiconductor device handling apparatus according to claim 2, wherein
the first moving device is disposed on an opposite side of the DUT with respect to the holding part, and
the second moving device is disposed on an opposite side of the DUT with respect to the optical probe.

4. The semiconductor device handling apparatus according to claim 2, wherein the first moving device moves the holding part and the second moving device relative to the contact part.

5. The semiconductor device handling apparatus according to claim 2, wherein
the first moving device comprises a support member to which the holding part is fixed, and
the second moving device is fixed to the support member and moves the optical probe relative to the holding part.

6. The semiconductor device handling apparatus according to claim 2, wherein the holding part comprises:
a contact surface that contacts the second surface of the DUT; and
a recess that opens to the contact surface, wherein
the optical probe is disposed in the recess such that the optical probe moves relative to the holding part.

7. The semiconductor device handling apparatus according to claim 5, wherein the holding part comprises:
a contact surface that contacts the second surface of the DUT; and
an insertion hole that opens to the contact surface, wherein
the optical probe is inserted into the insertion hole such that the optical probe moves relative to the holding part.

8. The semiconductor device handling apparatus according to claim 2, wherein
the first moving device is fixed to a base of the semiconductor device handling apparatus, and
the second moving device is fixed to the base independently of the first moving device.

9. The semiconductor device handling apparatus according to claim 1, wherein the optical probe comprises an optical transmission path that transmits the optical signal.

10. The semiconductor device handling apparatus according to claim 1, wherein the holding part comprises:
a contact surface that contacts the second surface of the DUT; and
a temperature adjusting mechanism that adjusts a temperature of the DUT via the contact surface.

11. The semiconductor device handling apparatus according to claim 1, wherein the holding part comprises:
a contact surface that contacts the second surface of the DUT; and
a suction holding mechanism that opens to the contact surface and holds the DUT by suction.

12. The semiconductor device handling apparatus according to claim 1, comprising
a first moving device that moves the holding part relative to the contact part and presses the DUT held by the holding part against the contact part and contact the terminal of the DUT with the contact part.

13. The semiconductor device handling apparatus according to claim 1, wherein the DUT comprises a die having the optical connection part.

14. The semiconductor device handling apparatus according to claim 13, wherein the DUT comprises a board that has the terminal and on which the die is mounted.

15. The semiconductor device handling apparatus according to claim 1, wherein the contact part includes a probe card comprising a contactor that contacts the terminal of the DUT.

16. A semiconductor device testing apparatus that tests a device under test (DUT), comprising:
a contact part that inputs and outputs an electrical signal to and from a terminal on a first surface of the DUT;
an optical probe that inputs and outputs an optical signal to and from an optical connection part disposed on a second surface of the DUT; and
a testing device connected to the contact part and the optical probe and that transmits the electrical signal and the optical signal, respectively.

17. A semiconductor device testing apparatus that tests a device under test (DUT), comprising:
a semiconductor device handling apparatus that:
moves the DUT so that a terminal on a first surface of the DUT contacts a contact part of a semiconductor device testing apparatus, and comprises:
a holding part that holds a second surface of the DUT; and
an optical probe that inputs and outputs an optical signal to and from an optical connection part on the second surface of the DUT;
the contact part that inputs and outputs an electrical signal to and from the terminal disposed; and
a testing device connected to the contact part and the optical probe and that transmits the electrical signal and the optical signal, respectively.
